(19) United States
(12) Patent Application Publication
(10) Pub. No.: US 2016/0372601 A1
(43) Pub. Date: Dec. 22, 2016

(54) NONVOLATILE SEMICONDUCTOR MEMORY DEVICE AND METHOD OF MANUFACTURING THE SAME

(71) Applicant: Kabushiki Kaisha Toshiba, Minato-ku (JP)

(72) Inventors: Takaya YAMANAKA, Yokkaichi (JP); Hiroto Sugiura, Yokkaichi (JP)

(73) Assignee: Kabushiki Kaisha Toshiba, Minato-ku (JP)

(21) Appl. No.: 14/929,503

(22) Filed: Nov. 2, 2015

Related U.S. Application Data
(60) Provisional application No. 62/182,939, filed on Jun. 22, 2015.

(51) Int. Cl. H01L 29/788; H01L 29/66; H01L 21/28; H01L 27/115; H01L 29/423; H01L 29/51

(52) U.S. Cl. CPC H01L 29/7883; H01L 29/42324; H01L 29/515; H01L 29/42364; H01L 21/28273; H01L 27/11521; H01L 29/66825

(57) ABSTRACT

A nonvolatile semiconductor memory device according to an embodiment comprises: a tunnel insulating film disposed on a semiconductor layer; a floating gate electrode disposed on the tunnel insulating film; a block insulating film disposed on the floating gate electrode; and a control gate electrode disposed on the block insulating film. The block insulating film is provided along a bottom surface and a side surface of the control gate electrode.

### CROSS REFERENCE TO RELATED APPLICATIONS

This application is based on and claims the benefit of priority from prior Japanese Patent Application NO. 62/182,939, filed on Jun. 22, 2015, the entire contents of which are incorporated herein by reference.

### FIELD

Embodiments described herein relate to a nonvolatile semiconductor memory device and a method of manufacturing the same.

### BACKGROUND

### Description of the Related Art

A memory cell configuring a nonvolatile semiconductor memory device such as a NAND type flash memory includes a semiconductor layer, a control gate, and a charge accumulation layer. The memory cell has its threshold voltage changed based on a charge accumulated in the charge accumulation layer and stores a magnitude of this threshold voltage as data. In recent years, further miniaturization has been required in such a nonvolatile semiconductor memory device. However, as a result of miniaturization, sometimes, a short circuit occurs between each of elements, or metal contamination occurs. Therefore, it has become required to achieve miniaturization while preventing occurrence of a short circuit or occurrence of metal contamination.

### BRIEF DESCRIPTION OF THE DRAWINGS

FIG. 1 is a block diagram of a nonvolatile semiconductor memory device according to a first embodiment.

FIG. 2 is a circuit diagram showing a configuration of part of the nonvolatile semiconductor memory device according to the first embodiment.

FIG. 3 is a planar layout diagram showing a configuration of part of the nonvolatile semiconductor memory device according to the first embodiment.

FIG. 4 is a cross-sectional view showing a configuration of part of the nonvolatile semiconductor memory device according to the first embodiment.

FIG. 5 is a cross-sectional view showing a configuration of part of the nonvolatile semiconductor memory device according to the first embodiment.

FIGS. 6 to 19 are cross-sectional views showing manufacturing steps of the nonvolatile semiconductor memory device according to the first embodiment.

FIG. 20 is a cross-sectional view showing a configuration of part of a nonvolatile semiconductor memory device according to a second embodiment.

FIG. 21 is a cross-sectional view showing a configuration of part of the nonvolatile semiconductor memory device according to the second embodiment.

FIGS. 22 to 34 are cross-sectional views showing manufacturing steps of the nonvolatile semiconductor memory device according to the second embodiment.

### DETAILED DESCRIPTION

A nonvolatile semiconductor memory device described below comprises: a tunnel insulating film disposed on a semiconductor layer; a floating gate electrode disposed on the tunnel insulating film; a block insulating film disposed on the floating gate electrode; and a control gate electrode disposed on the block insulating film. The block insulating film is provided along a bottom surface and a side surface of the control gate electrode.

Embodiments of a semiconductor memory device and a method of manufacturing the same will be described below with reference to the drawings.

### First Embodiment

### Overall Configuration

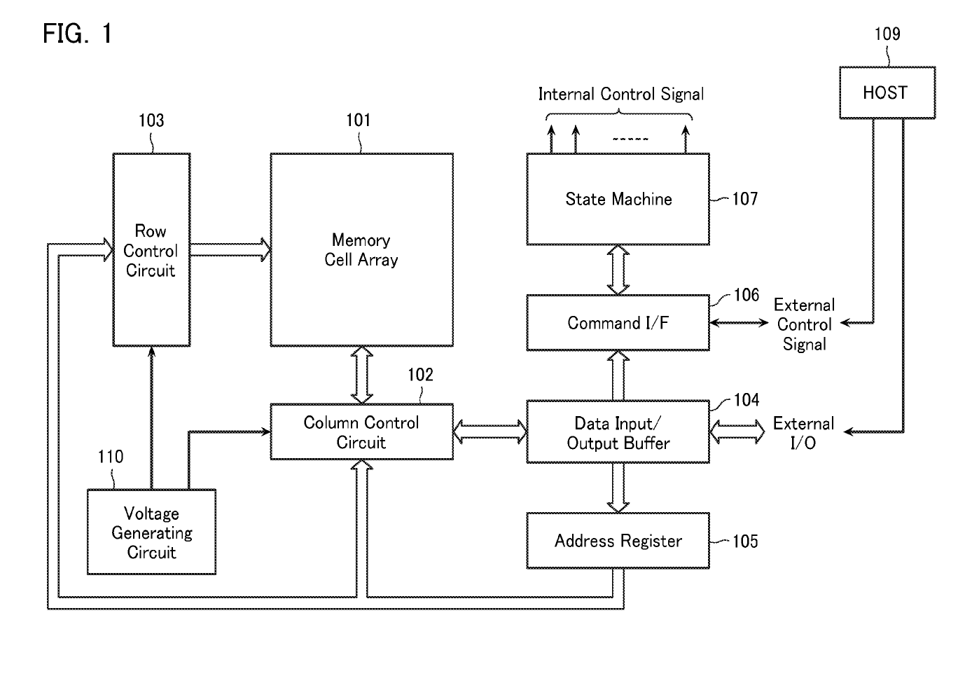

FIG. 1 is a block diagram of a nonvolatile semiconductor memory device according to a first embodiment. This nonvolatile semiconductor memory device includes a memory cell array 101 that has a plurality of memory cells MC disposed substantially in a matrix therein and that comprises a bit line BL and a word line WL disposed orthogonally to each other and connected to these memory cells MC. Provided in a periphery of this memory cell array 101 are a column control circuit 102 and a row control circuit 103. The column control circuit 102 controls the bit line BL and performs data erase of the memory cell, data write to the memory cell, and data read from the memory cell. The row control circuit 103 selects the word line WL and applies a voltage for data erase of the memory cell, data write to the memory cell, and data read from the memory cell.

A data input/output buffer 104 is connected to an external host 109, via an I/O line, and receives write data, receives an erase command, outputs read data, and receives address data or command data. The data input/output buffer 104 sends received write data to the column control circuit 102, and receives data read from the column control circuit 102 to be outputted to external. An address supplied to the data input/output buffer 104 from external is sent to the column control circuit 102 and the row control circuit 103 via an address register 105.

Moreover, a command supplied to the data input/output buffer 104 from the host 109 is sent to a command interface 106. The command interface 106 receives an external control signal from the host 109, determines whether data inputted to the data input/output buffer 104 is write data or a command or an address, and, if a command, receives the data and transfers the data to a state machine 107 as a command signal.

The state machine 107 performs management of this nonvolatile memory overall, receives a command from the host 109, via the command interface 106, and performs management of read, write, erase, input/output of data, and so on.

In addition, it is also possible for the external host 109 to receive status information managed by the state machine 107 and judge an operation result. Moreover, this status information is utilized also in control of write and erase.

Furthermore, the state machine 107 controls a voltage generating circuit 110. This control enables the voltage generating circuit 110 to output a pulse of any voltage and any timing.

Now, the pulse formed by the voltage generating circuit 110 can be transferred to any wiring line selected by the column control circuit 102 and the row control circuit 103. These column control circuit 102, row control circuit 103, state machine 107, voltage generating circuit 110, and so on, configure a control circuit in the present embodiment.

[Memory Cell Array 101]

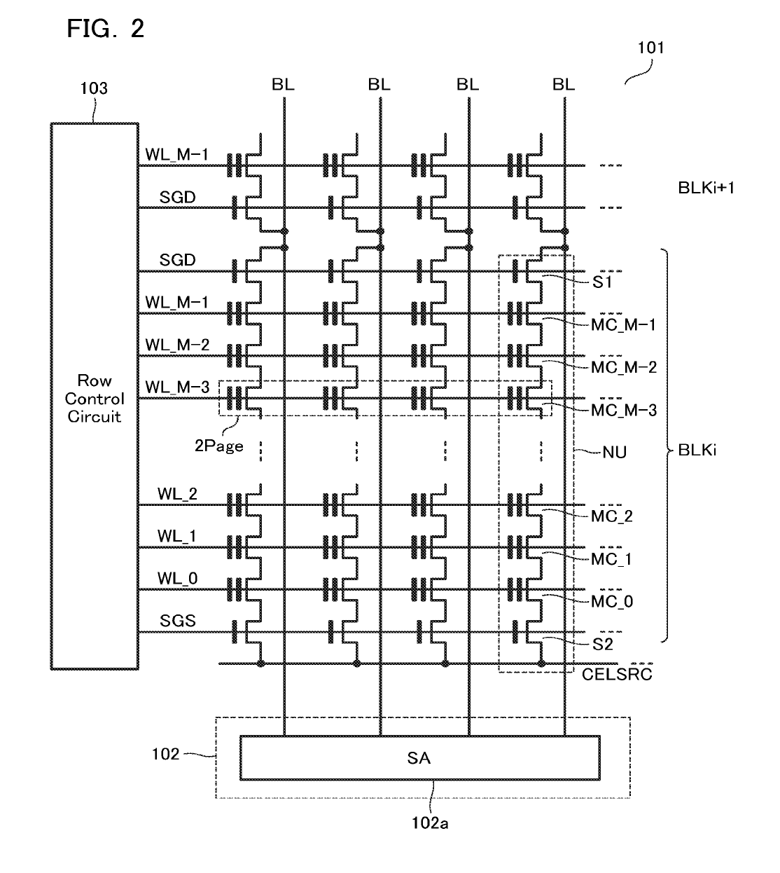

FIG. 2 is a circuit diagram showing a configuration of the memory cell array 101. As shown in FIG. 2, the memory cell array 101 is configured having NAND cell units NU arranged therein, the NAND cell units NU each having select gate transistors S1 and S2 respectively connected to both ends of a NAND string, the NAND string having M electrically rewritable nonvolatile memory cells MC_0 to MC_M−1 connected in series therein sharing a source and a drain.

The NAND cell unit NU has one end (a select gate transistor S1 side) thereof connected to the bit line BL, and the other end (a select gate transistor S2 side) thereof connected to a common source line CELSRC. Gate electrodes of the select gate transistors S1 and S2 are connected to select gate lines SGD and SGS. Moreover, control gate electrodes of the memory cells MC_0 to MC_M−1 are respectively connected to word lines WL_0 to WL_M−1. The bit line BL is connected to a sense amplifier 102a of the column control circuit 102, and the word lines WL_0 to WL_M−1 and select gate lines SGD and SGS are connected to the row control circuit 103.

In the case of 2 bits/cell where 2 bits of data are stored in one memory cell MC, data stored in the plurality of memory cells MC connected to one word line WL configures two pages (an upper page UPPER and a lower page LOWER) of data.

One block BLK is formed by the plurality of NAND cell units NU sharing the word line WL. One block BLK forms a single unit of a data erase operation. The number of word lines WL in one block BLK in one memory cell array 101 is M, and in the case of 2 bits/cell, the number of pages in one block is M×2.

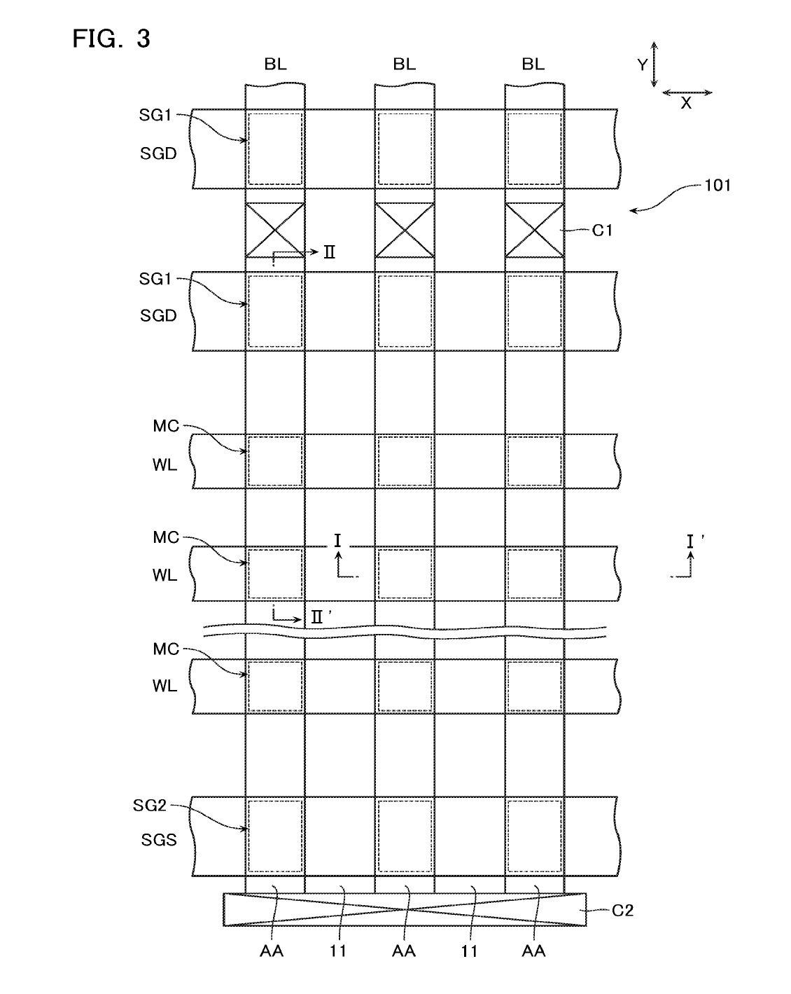

Next, details of the configuration of the memory cell array 101 will be described with reference to FIGS. 3 to 5.

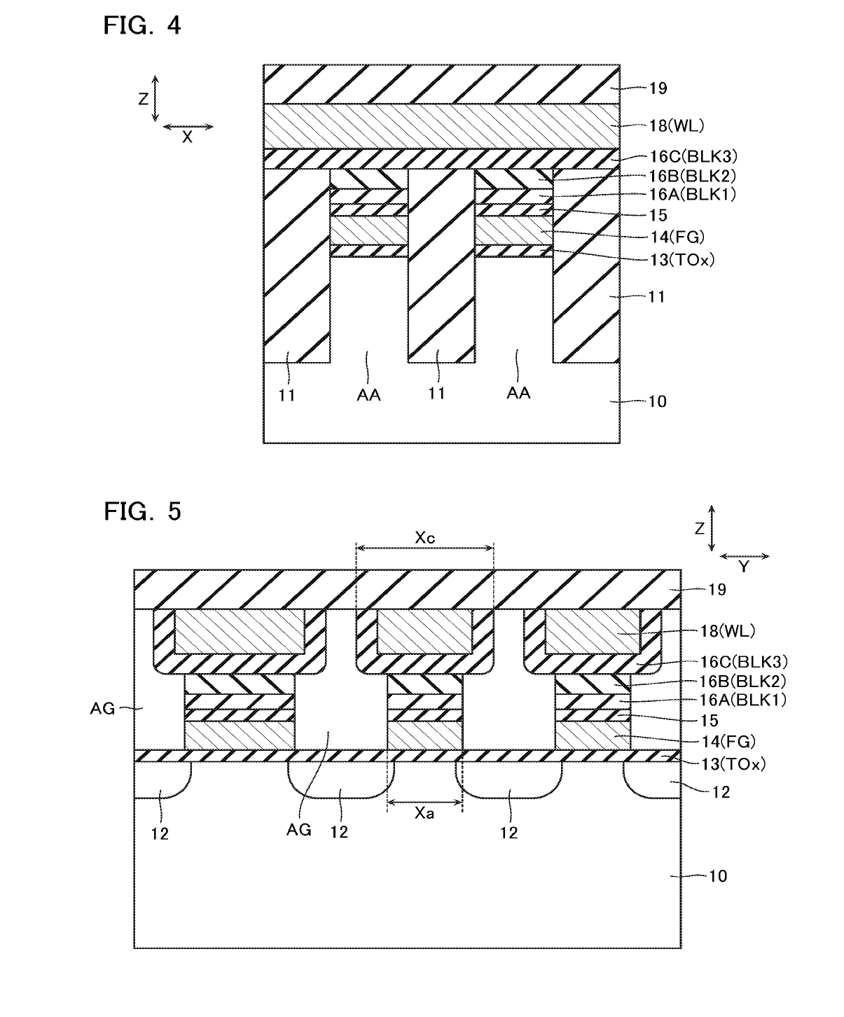

FIG. 3 is a planar layout view of the memory cell array 101, and FIGS. 4 and 5 are cross-sectional views taken along the lines I-I′ and II-II′, respectively, of FIG. 3.

As shown in FIG. 3, the memory cell array 101 has a plurality of the word lines WL and bit lines BL arranged therein intersecting each other, and has the memory cell MC formed therein at each of intersections of these word lines WL and bit lines BL.

The plurality of memory cells MC aligned in a bit line BL direction are connected in series, and configure one memory string. As will be mentioned later, a semiconductor substrate where the memory cell MC is formed is isolated into a plurality of active areas AA by an element isolation insulating film 11 formed having a Y direction as its longitudinal direction, and the memory string is formed along this active area AA. The plurality of memory strings aligned in an X direction are commonly connected to an identical word line WL, and form one memory block. The memory block is a minimum unit of the data erase operation. Note that it is also possible for at least one of the plurality of memory cells MC included in the memory string to be configured as a dummy cell not employed in data storage.

One end of the memory string is connected to the bit line BL via a drain side select gate transistor SG1. The bit line BL and the drain side select gate transistor SG1 are connected by a contact C1.

In addition, the other end of the memory string is connected to an unillustrated source line SL via a source side select gate transistor SG2. The source line SL and the source side select gate transistor SG2 are connected via a source side contact C2.

A gate of the drain side select gate transistor SG1 is connected to the drain side select gate line SGD arranged parallel to the word line WL. Moreover, a gate of the source side select gate transistor SG2 is connected to the source side select gate line SGS arranged parallel to the word line WL. Now, a direction in which the word line WL extends is defined as a word line direction (X direction), and a direction in which the bit line BL extends is defined as a bit line direction (Y direction).

Next, a cross-sectional structure of the memory cell MC will be described with reference to FIGS. 4 and 5.

As shown in FIG. 4, the memory cell MC is formed on a semiconductor substrate 10. Element isolation insulating films 11 that extend having the Y direction as their longitudinal direction are formed with a certain spacing in the X direction, in a surface of this semiconductor substrate 10. The element isolation insulating film 11 is formed from, for example, silicon oxide (SiO₂). A region of the semiconductor substrate 10 sandwiched by the element isolation insulating films 11 is the active area AA where the memory string (memory cell) is formed. That is, the surface of the semiconductor substrate 10 is electrically isolated into the plurality of active areas AA by the element isolation insulating film 11. The active areas AA extend having the Y direction as their longitudinal direction and are formed with a certain spacing in the X direction, similarly to the element isolation insulating films 11.

As shown in FIG. 5, the plurality of memory cells MC each comprise: a plurality of source/drain diffusion layers 12 disposed in the surface of the semiconductor substrate 10; a gate insulating film 13 (tunnel insulating film) disposed on at least a channel region between these source/drain diffusion layers 12; and a floating gate electrode 14 disposed on the gate insulating film 13. A film thickness of the gate insulating film 13 may be set to about 6 nm, for example. Note that the select gate transistors SG1 and SG2 also have a cross-sectional structure in the Y direction which is substantially identical to that of the memory cell MC. However, the select gate transistors SG1 and SG2 may adopt a structure in which a control gate electrode 16 and the floating gate electrode 14 are short-circuited via a trench penetrating a gate insulating film 13.

Moreover, a film thickness of the floating gate electrode 14 may be set to about 10 to 25 nm, for example. Note that it is also possible for the source/drain diffusion layer 12 to be omitted when a distance between the plurality of fellow memory cells MC is short. This is because a so-called fringe effect makes it possible for a conducting path penetrating channel regions of the plurality of memory cells MC to be generated even without the source/drain diffusion layer 12. The source/drain diffusion layer 12 may be formed by performing ion implantation of an n type impurity (phosphorus (P), and so on) in a self-aligning manner using a gate electrode structure as a mask, and then diffusing the impurity by heat treatment for 30 seconds at 955° C.

Furthermore, this memory cell MC comprises the insulating film 15 disposed on the floating gate electrode 14. This insulating film 15 is formed by, for example, silicon nitride (SiN). A film thickness of the insulating film 15 may be set to about 2 nm, for example. Although illustration thereof is omitted, a ruthenium layer (Ru) functioning as a second charge accumulation film is formed on a surface of the insulating film 15. The insulating film 15 is a film for electrically insulating from each other this ruthenium layer and the floating gate electrode 14. The existence of this insulating film 15 and the ruthenium layer enables an aspect ratio of the floating gate electrode 14 to be reduced. A block insulating film 16 is formed on this insulating film 15. As an example, this block insulating film 16 is configured by a lower layer insulating film 16A configured from hafnium oxide (HfO₂), an intermediate insulating film 16B configured from silicon oxide (SiO₂), and an upper layer insulating film 16C configured from hafnium oxide (HfO₂). The lower layer insulating film 16A and the upper layer insulating film 16C are so-called high permittivity insulating films (High-K), and besides hafnium oxide (HfO₂), may use the likes of aluminum oxide (Al₂O₃), titanium oxide (TiO₂), tantalum oxide (Ta₂O₅), hafnium silicate (HfSiO₄), and hafnium silicon oxynitride (HfSiON). The block insulating film 16 described herein has a three-layer structure of the insulating films 16A to 16C, but is not limited to this, and may adopt a single material film, or may be configured as a two-layer stacked film. Moreover, it may also be configured as a stacked film of four or more layers.

A conductive layer 18 acting as the word line WL is deposited on this block insulating film 16 via an unillustrated barrier metal. As an example, film thicknesses of the lower layer insulating film 16A, the intermediate insulating film 16B, and the upper layer insulating film 16C may each be set to about 4 to 5 nm. In the example illustrated in this FIG. 4, a CMP method is executed whereby the intermediate insulating film 16B has a height in a Z direction of its upper surface substantially matching a height in the Z direction of an upper surface of the element isolation insulating film 11. Therefore, the lower layer insulating film 16A and the intermediate insulating film 16B are disposed only at a position between the element isolation insulating films 11. Moreover, the upper layer insulating film 16C is formed having an X axis direction as its longitudinal direction similarly to the word line WL, on the upper surfaces of the planarized intermediate insulating film 16B and element isolation insulating film 11. In addition, this upper layer insulating film 16C, contrary to the lower layer insulating film 16A and intermediate insulating film 16B, is formed not only on a bottom surface of the conductive film 18, but also continuously on a side surface in the X direction of the conductive layer 18. The reason the upper layer insulating film 16C is configured in such a shape is due to a later-described method of manufacturing being adopted. As a result of such a shape and method of manufacturing being adopted, metal contamination from the conductive film 18 (metal in the conductive film 18 diffusing, reaching the block insulating film or tunnel insulating film, and degrading properties of these films) can be suppressed. Moreover, forming the upper layer insulating film 16C so as to also cover the side surface of the conductive film 18 as mentioned above makes it unnecessary to newly form a sidewall insulating film on the side surface of the conductive film 18. Therefore, a width of an air gap AG between the memory cells can be broadly taken. In the case of a configuration example of FIG. 5, a sidewall of the floating gate electrode 14 is not covered by a sidewall insulating film or the like, and contacts the air gap AG directly, and two adjacent floating gate electrodes 14 are insulated and isolated by the air gap AG only. The air gap AG has a permittivity which is smaller compared to that of a sidewall insulating film configured from the likes of a silicon oxide film. Therefore, enlarging the width of the air gap AG makes it possible to suppress inter-cell interference.

Moreover, as shown in FIG. 5, the upper layer insulating film 16C has its width Xc in the X direction set larger than a width Xa in the X direction of the floating gate electrode 14. On the other hand, widths in the X direction of the lower layer insulating film 16A and the intermediate insulating film 16B are substantially identical to the width Xa of the floating gate electrode 14.

As a result of such a shape and method of manufacturing being adopted, a width of the conductive film 18 can be enlarged to reduce a resistance of the word line WL. The conductive film 18 is formed by a metal such as tungsten (W). However, this is one example of a preferred embodiment, and it is also possible to adopt a structure where Xa and Xc are substantially equal.

Note that an interface layer may exist between the charge accumulation layer 15 and the block insulating film 16, and between the block insulating film 16 and a barrier metal 17.

The memory cell shown in FIGS. 2 and 3 has a so-called flat cell structure in which the upper surface of the element isolation insulating film 11 is in a higher position than a surface of the floating gate electrode 14. However, this is merely one example, and the technology of this embodiment may be applied also to a structure in which the upper surface of the element isolation insulating film 11 is in a lower position than the surface of the floating gate electrode 14 (also called a rocket cell structure).

[Method of Manufacturing]

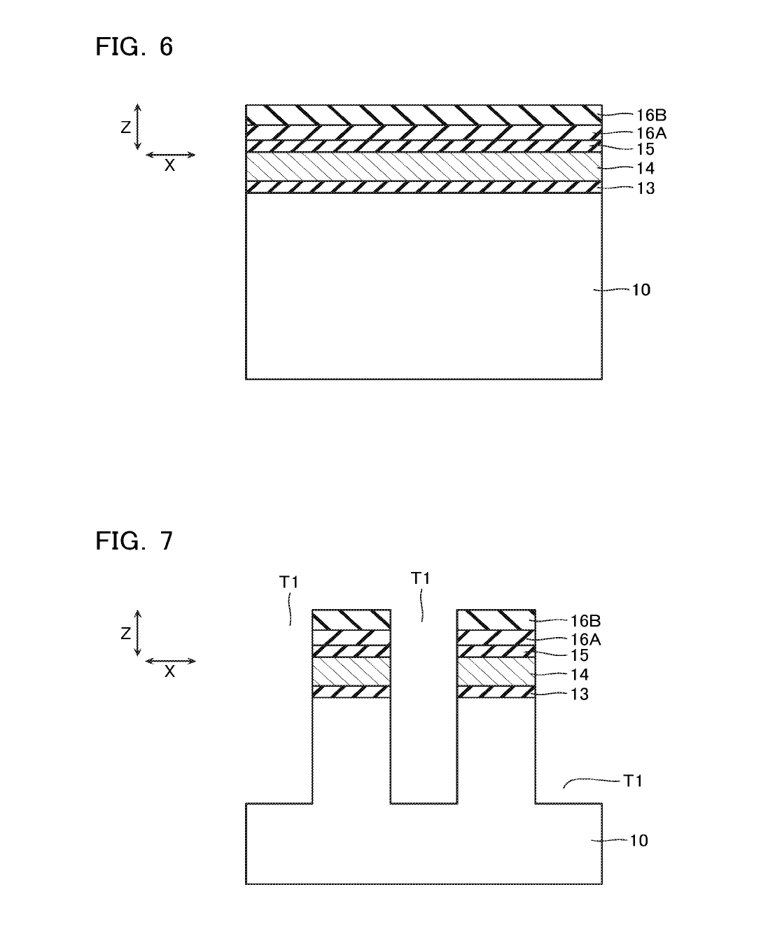

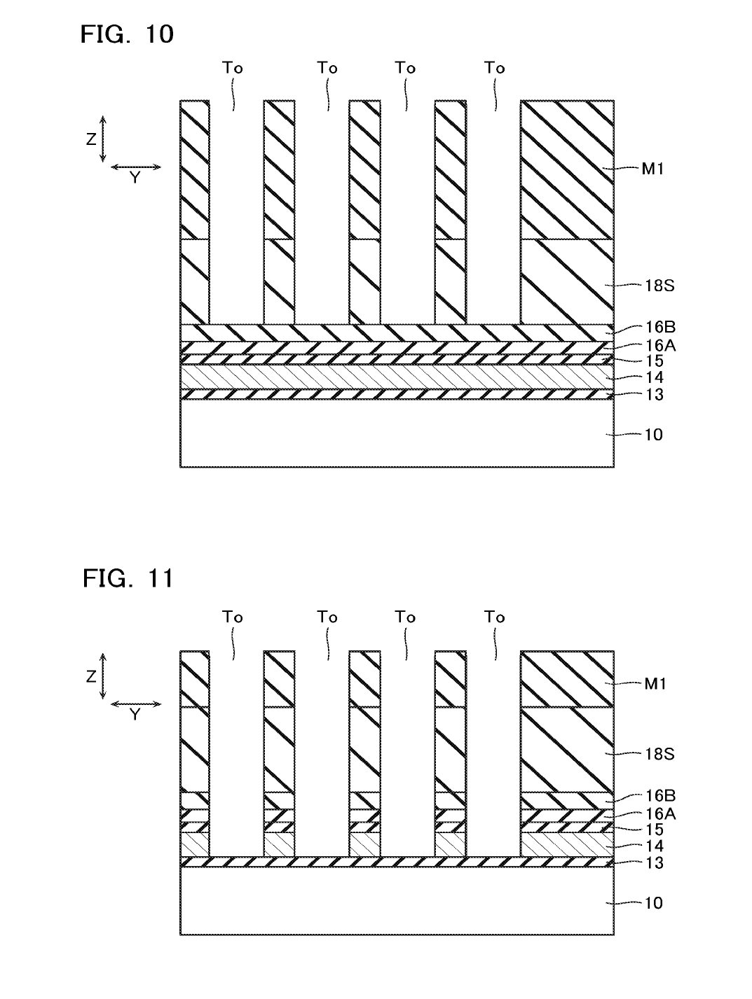

Next, a method of manufacturing a nonvolatile semiconductor memory device according to the present embodiment will be described with reference to FIGS. 6 to 19. FIGS. 6 to 9 show cross-sections along the X direction of FIG. 3; and FIGS. 10 to 19 show cross-sections along the Y direction of FIG. 3.

First, as shown in FIG. 6, materials which will be the gate insulating film 13 (tunnel insulating film), the floating gate electrode 14, the insulating film 15, the lower layer insulating film 16A, and the intermediate insulating film 16B (for example, a silicon oxide film, polysilicon, a silicon nitride film, a hafnium oxide film, and a silicon oxide film) are deposited sequentially from below on the semiconductor substrate 10, using the likes of a CVD method.

Then, as shown in FIG. 7, trenches T1 that penetrate these stacked materials and the semiconductor substrate 10 and which have the Y direction as their longitudinal direction, are formed with a certain spacing in the X direction. As shown in FIG. 8, the element isolation insulating film 11 whose material is, for example, a silicon oxide film (SiO₂), is formed in this trench T1. Note that the element isolation insulating film 11 is polished using the likes of a CMP method until a position of the height of its upper surface substantially matches a position of the height of the surface of the intermediate insulating film 16B.

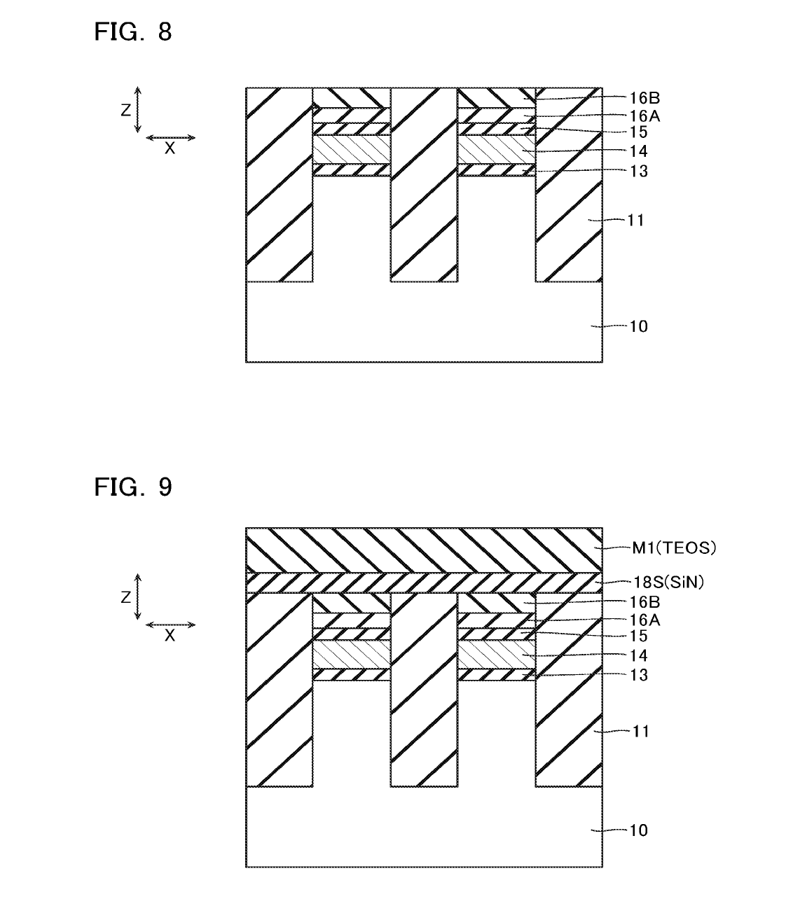

Then, as shown in FIG. 9, a sacrifice film 18S configured from a silicon nitride film, for example, is deposited so as to cover an entire surface of a stacked body on the semiconductor substrate 10, and a mask material M1 configured from a TEOS film, for example, is further deposited on an upper surface of the sacrifice film 18S. As will be mentioned later, this sacrifice film 18S is formed in order to be removed by etching and have the conductive film 18 formed in a cavity portion left after the etching.

As shown in FIG. 10, the sacrifice film 18S and the mask material Ml thus deposited are divided by trenches To formed having the X direction as their longitudinal direction with a certain spacing in the Y direction. As shown in FIG. 11, this trench To is further etched so as to penetrate the floating gate electrode 14, the insulating film 15, the lower layer insulating film 16A, and the intermediate insulating film 16B below the sacrifice film 18S.

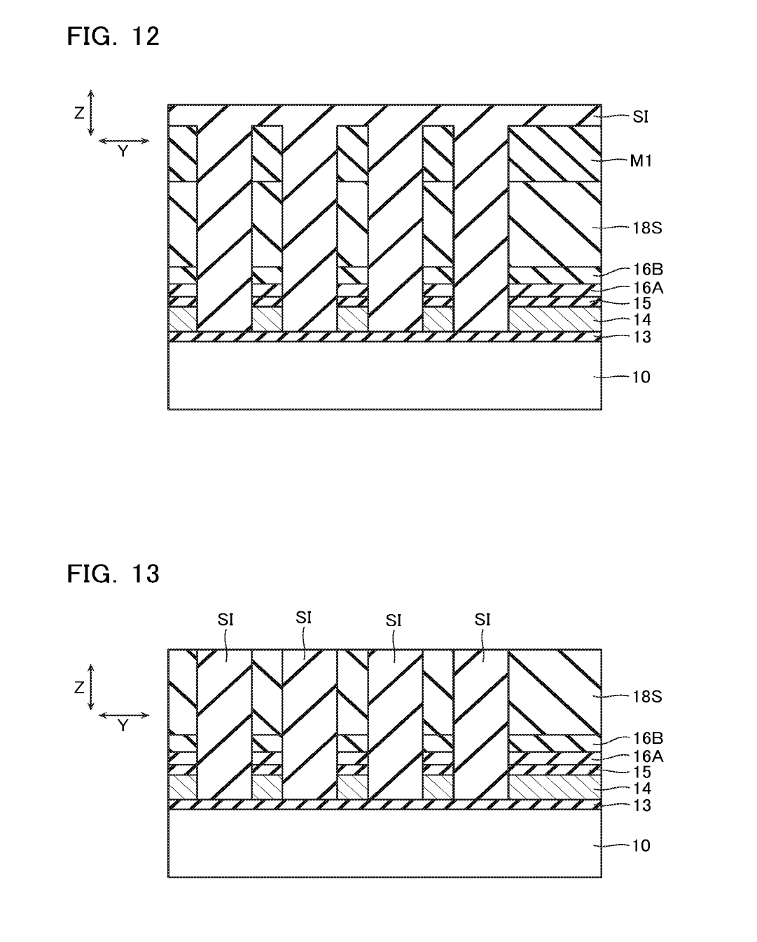

Then, as shown in FIG. 12, a sacrifice film SI configured from polysilazane, for example, is formed so as to cover the inside of this trench To and a surface of the mask material Ml. It is also possible to select another insulating film having excellent implanting properties, for example, a TEOS film, instead of polysilazane.

Next, as shown in FIG. 13, a CMP method is executed to polish/remove the mask material M1 and the sacrifice film SI, and expose a surface of the sacrifice film 18S.

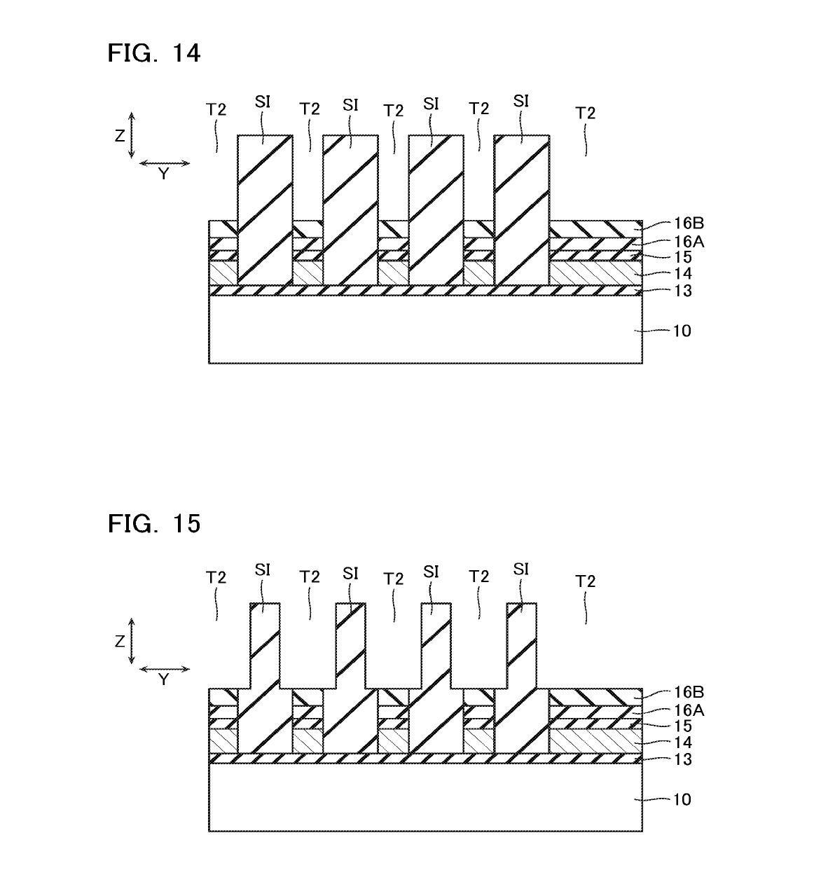

Then, as shown in FIG. 14, wet etching using a hot phosphoric acid solution, for example, is executed to remove the sacrifice film 18S. After the sacrifice film 18S has been removed, a cavity portion T2 is formed between the sacrifice films SI.

Next, as shown in FIG. 15, wet etching using a fluoric acid solution, for example, is further executed to perform etching of the sacrifice film SI configured from polysilazane and thereby enlarge a width of the cavity portion T2. As an example, wet etching is continued until the width of the cavity portion T2 is about 17 nm.

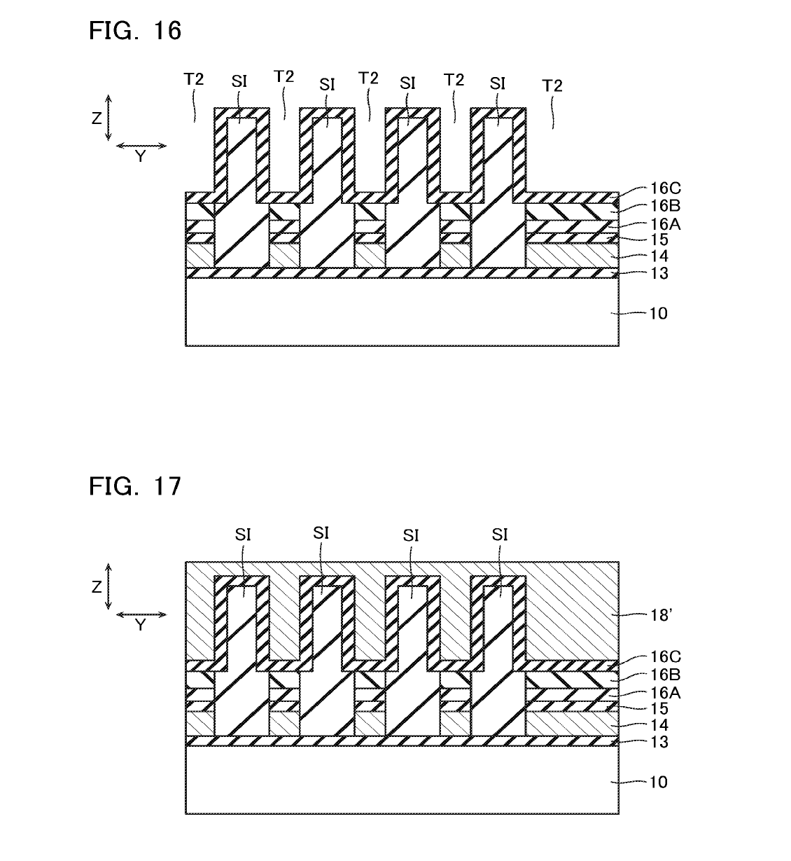

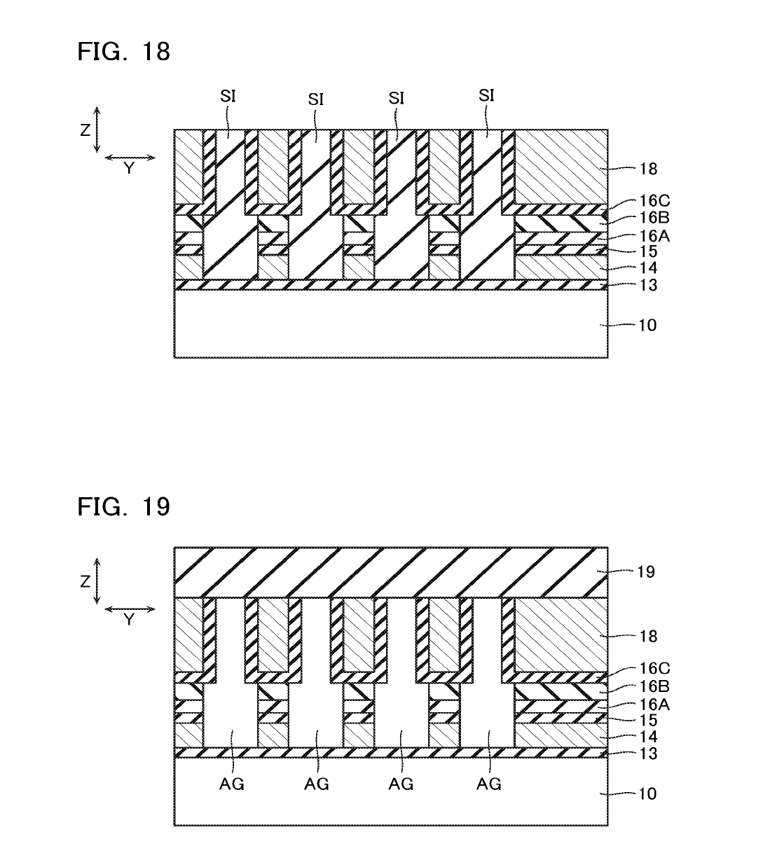

Then, as shown in FIG. 16, an ALD method or the like is employed to deposit the upper layer insulating film 16C whose material is hafnium oxide, for example, on an entire surface of a structure on the semiconductor substrate 10 including an inner wall of this cavity portion T2. Then, as shown in FIG. 17, a conductive film 18′ whose material is the likes of tungsten, for example, is deposited using a sputtering method, for example, so as to fill the inside of the cavity portion T2, until the cavity portion T2 is implanted. The conductive film 18′ deposited on the outside of the cavity portion T2 is removed by a CMP method, whereby the previously mentioned conductive film 18 is formed as shown in FIG. 18.

Then, as shown in FIG. 19, wet etching using a fluoric acid solution is again executed to remove the sacrifice film SI. As a result, the air gap AG is formed between gate electrode structures (from the floating gate electrode 14 to the conductive layer 18) of a plurality of the memory cells MC. After the air gap AG has been formed, an inter-layer insulating film 19 configured from the likes of a silane film, for example, is deposited on the air gap AG and an upper surface of the conductive film 18. The silane film has low implanting properties, hence the air gap AG is not implanted by the inter-layer insulating film 19, and the air gap AG remains.

Due to the above-described method of manufacturing, the conductive film 18 is formed by the sacrifice film 18S being formed and then the conductive film 18 being implanted in the cavity portion after the sacrifice film 18S has been removed by etching. That is, in the method of manufacturing of this embodiment, the conductive film 18 is formed in a final stage in formation of the gate electrode structure of the memory cell MC, moreover, the conductive film 18 has its bottom surface and side surface covered by the third insulating film 16C. Therefore, even if the conductive film 18 is formed by a metal material such as tungsten, for example, diffusion of that metal material is suppressed by the third insulating film 16C, hence metal contamination can be prevented.

In the case where, as in a conventional method of manufacturing, the conductive layer 18 is made a target of etching processing simultaneously to the floating gate electrode 14, and so on, of a lower layer, it was required to form a sidewall insulating film on the side surface of the conductive film 18 after the processing. In the present embodiment, this sidewall insulating film becomes unnecessary, hence the number of steps can be reduced.

Moreover, in this embodiment, the sacrifice film 18S, after being formed in this way to be etching processed along with the block insulating film 16, is removed and the conductive film 18 is formed by being implanted in the cavity portion after removal of the sacrifice film 18S. In the case where, as in the conventional method of manufacturing, the conductive layer 18 is etching processed simultaneously to the floating gate electrode 14, and so on, of a lower layer, there is a risk that the gate electrode structure as a whole easily attains a tapered shape, and that over-etching occurs in the conductive film 18 of an upper layer, or that conversely an etching residue of the floating gate electrode 14 of a lower layer increases whereby a short circuit occurs between the floating gate electrodes. Due to the present embodiment, the floating gate electrode 14 is etching processed previously along with the sacrifice film 18S, and so on, hence floating gate electrode processing itself is also easy, hence the etching residue does not occur. Moreover, after the sacrifice film 18S has been removed by etching, the conductive film 18 is formed by being implanted in the cavity portion after removal of the sacrifice film 18S. Therefore, over-etching does not occur in processing of the conductive film 18, and the above-mentioned kind of over-etching does not occur. In such a way, the method of manufacturing of the present embodiment makes it possible to process the floating gate electrode 14 and the conductive film 18 without causing over-etching or the etching residue to occur.

Moreover, by adopting the step of FIG. 15, the conductive film 18 can be given a broader structure than the floating gate electrode 14, and so on, and a resistance value of the word line WL can be prevented from rising. Note that the step of FIG. 15 may also be omitted, if the resistance value of the conductive film 18 can be sufficiently lowered. In this case, a width in the X direction of the conductive film 18 becomes smaller than that of the floating gate electrode 14 to an extent of a film thickness portion of the third insulating film 16C.

### Second Embodiment

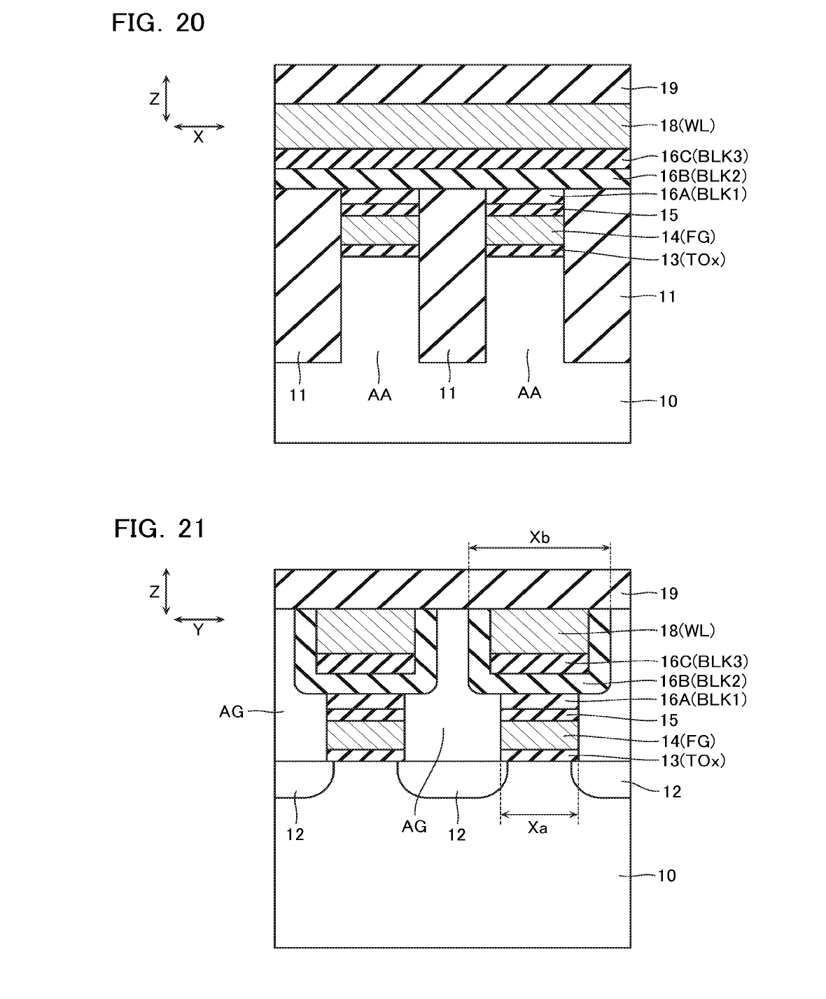

Next, a nonvolatile semiconductor memory device according to a second embodiment will be described with reference to FIGS. 20 and 21. An overall configuration of the nonvolatile semiconductor memory device of this second embodiment has a circuit configuration and a planar layout of the memory cell array 101 which are identical to those of the first embodiment (FIGS. 1 to 3), hence duplicated descriptions thereof will be omitted. However, a cross-sectional structure of the memory cell is different from that of the first embodiment. Moreover, FIG. 20 is a cross-sectional view taken along the line I-I′ of FIG. 3 and FIG. 21 is a cross-sectional view taken along the line II-II′ of FIG. 3, of the nonvolatile semiconductor memory device according to the second embodiment. In FIGS. 20 and 21, configurations identical to those of the first embodiment are assigned with identical reference symbols to those assigned in FIGS. 4 and 5, and duplicated descriptions thereof will be omitted below.

In the cross-sectional structure of this second embodiment, the intermediate insulating film 16B positioned intermediately, of the three insulating films of the block insulating film 16, is formed along the bottom surface and side surface of the conductive film 18, and this differs from the first embodiment.

On the other hand, the upper layer insulating film 16C is provided only on a bottom surface of an inner wall of the intermediate insulating film 16B, and the lower layer insulating film 16A is provided between a bottom surface of the intermediate insulating film 16B and the insulating film 15. The side surface and bottom surface of the conductive film 18 are covered by part of the block insulating film 16 (second insulating film 16B) also in this second embodiment, and this is shared with the first embodiment. Therefore, this second embodiment can also display similar advantages to those of the first embodiment.

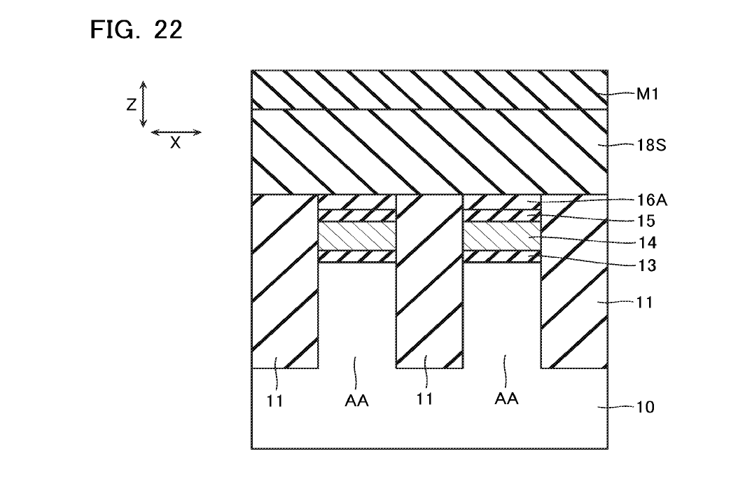

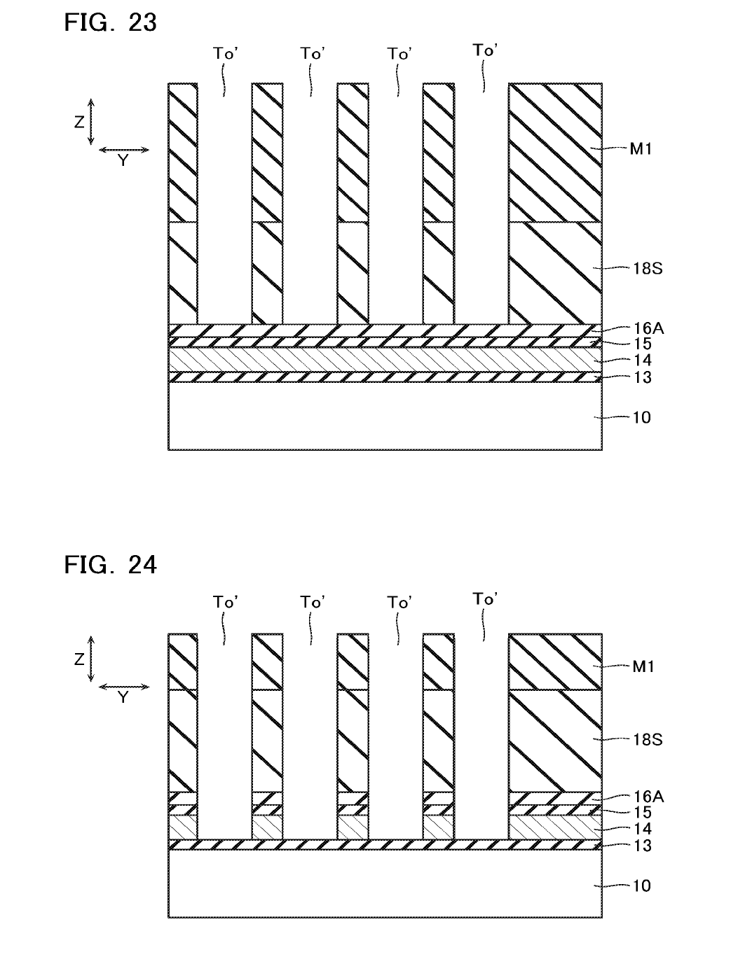

Next, a method of manufacturing a nonvolatile semiconductor memory device of this second embodiment will be described with reference to FIGS. 22 to 34. FIG. 22 shows a cross-section along the X direction of FIG. 3; and FIGS. 23 to 34 show cross-sections along the Y direction of FIG. 3.

First, a structure of the kind shown in FIG. 22 is made in a substantially similarly way to in FIGS. 6 to 9 of the method of manufacturing of the first embodiment. The difference with FIG. 9 of the first embodiment is that in FIG. 9, the lower layer insulating film 16A is already formed on the active area AA, whereas in FIG. 22, the intermediate insulating film 16B is not yet formed on the active area AA. As will be mentioned later, the intermediate insulating film 16B is deposited after the sacrifice film 18S has been removed by etching.

Then, as shown in FIG. 23, the sacrifice film 18S and the mask M1 are divided by trenches To′ formed having the X direction as their longitudinal direction with a certain spacing in the Y direction. As shown in FIG. 24, this trench To′ is further etched so as to penetrate the floating gate electrode 14, the insulating film 15, and the lower layer insulating film 16A below the sacrifice film 18S.

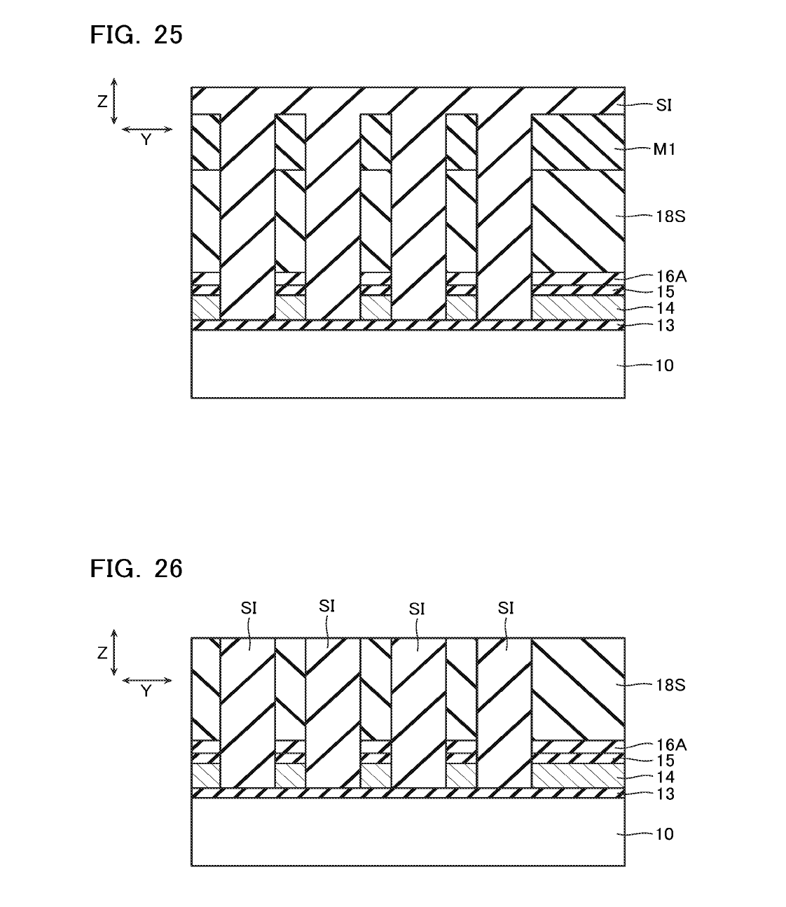

Then, as shown in FIG. 25, the sacrifice film SI configured from polysilazane, for example, is formed so as to cover the inside of this trench To′ and the surface of the mask material M1. It is also possible to select another insulating film having excellent implanting properties, for example, a TEOS film, instead of polysilazane.

Next, as shown in FIG. 26, a CMP method is executed to polish/remove the mask material Ml and the sacrifice film SI, and expose the surface of the sacrifice film 18S.

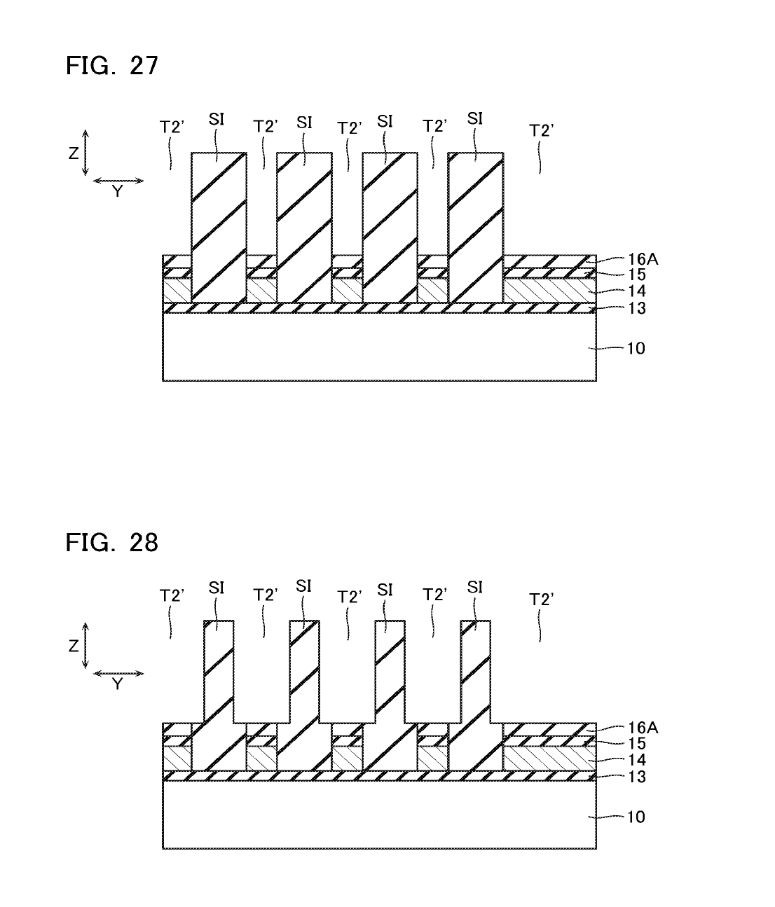

Then, as shown in FIG. 27, wet etching using a hot phosphoric acid solution, for example, is executed to remove the sacrifice film 18S. After the sacrifice film 18S has been removed, a cavity portion T2′ is formed between the sacrifice films SI.

Next, as shown in FIG. 28, wet etching using a fluoric acid solution, for example, is further executed to perform etching of the sacrifice film SI configured from polysilazane and thereby enlarge a width of the cavity portion T2′.

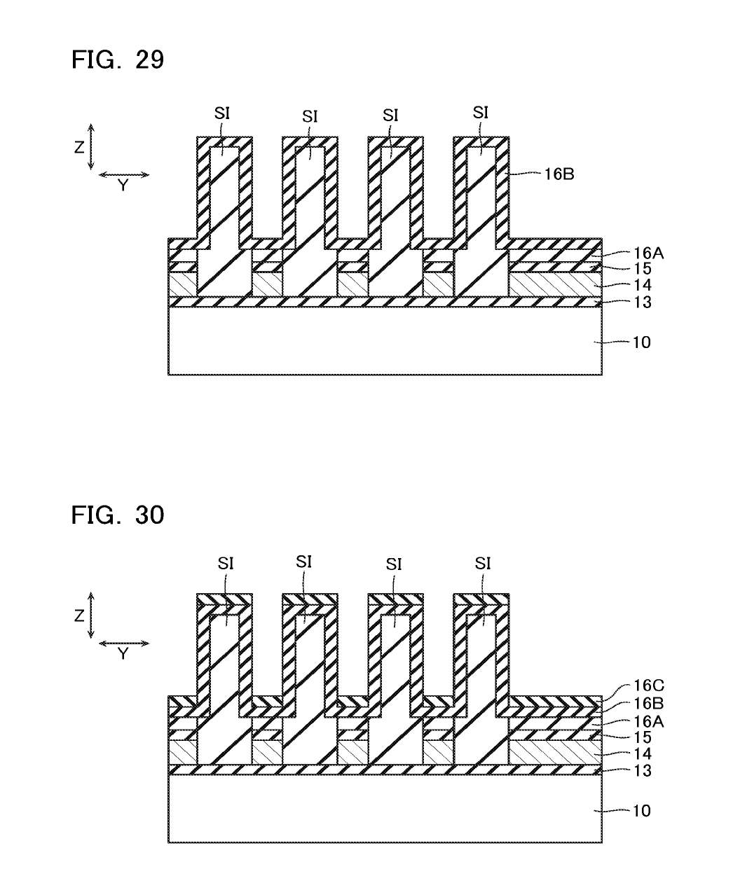

Then, as shown in FIG. 29, an ALD method or the like is employed to deposit the intermediate insulating film 16B whose material is silicon oxide, for example, on an entire surface of a structure on the semiconductor substrate 10 including an inner wall of this cavity portion T2′. Then, as shown in FIG. 30, a sputtering method is employed to deposit the upper layer insulating film 16C whose material is hafnium oxide, on this intermediate insulating film 16B. When the sputtering method is adopted, the upper layer insulating film 16C is barely formed on a sidewall of the cavity portion T2′, and is deposited only on a bottom surface of the cavity portion T2′ and the outside of the cavity portion T2′.

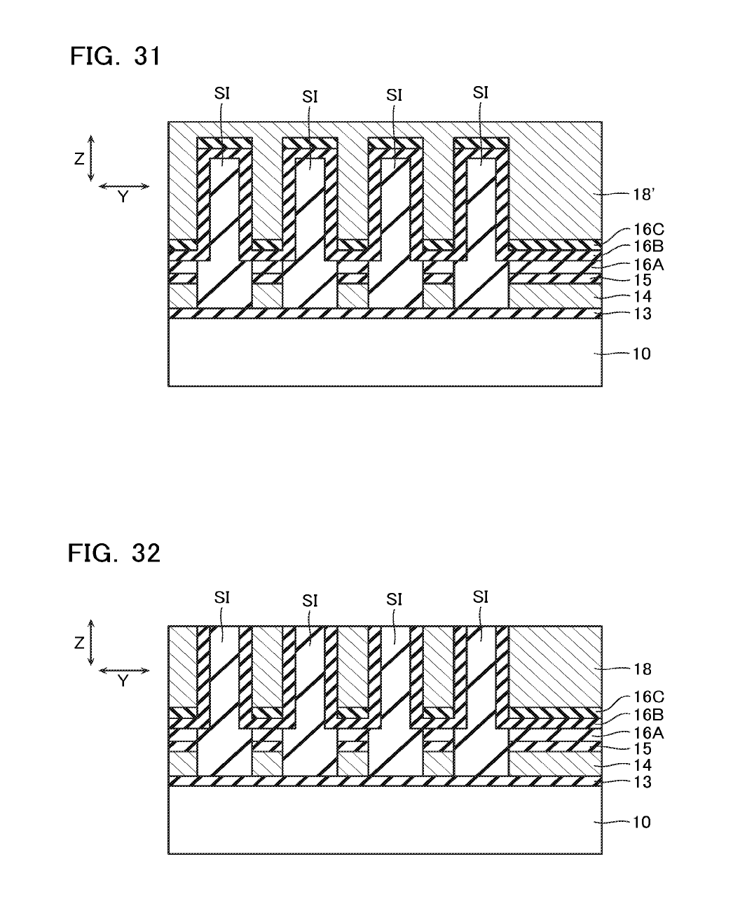

Then, as shown in FIG. 31, the conductive film 18′ configured from tungsten, for example, is deposited using a sputtering method, for example, so as to fill in the cavity portion T2′. Then, as shown in FIG. 32, a CMP method is executed to remove the intermediate insulating film 16B, the upper layer insulating film 16C, and the conductive film 18′ formed on the outside of the cavity portion T2′, and form the conductive film 18 in the cavity portion T2′.

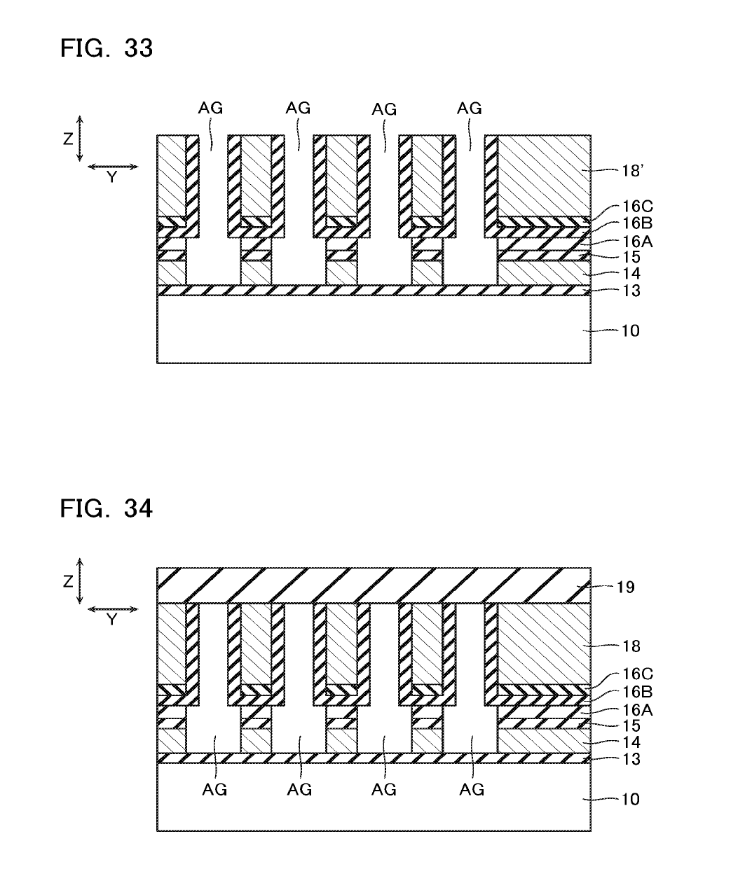

Then, as shown in FIG. 33, wet etching using a fluoric acid solution is again executed to remove the sacrifice film SI. As a result, the air gap AG is formed between the gate electrode structures (from the floating gate electrode 14 to the conductive layer 18) of a plurality of the memory cells MC. After the air gap AG has been formed, the inter-layer insulating film 19 configured from the likes of a silane film, for example, is deposited on the air gap AG and the upper surface of the conductive film 18. The silane film has low implanting properties, hence the air gap AG is not implanted by the inter-layer insulating film 19, and the air gap AG remains.

As described above, due to the structure and method of manufacturing of the present embodiment, the conductive film 18 has its bottom surface and side surface covered by the insulating film 16B, hence metal contamination from the conductive film 18 can be suppressed, similarly to in the first embodiment.

Moreover, it becomes unnecessary for a sidewall insulating film to be newly formed on the side surface of the conductive film 18, hence the width of the air gap AG between the memory cells can be broadly taken, and inter-cell interference can be suppressed.

[Others]

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a tunnel insulating film disposed on a semiconductor layer;
a floating gate electrode disposed on the tunnel insulating film;
a block insulating film disposed on the floating gate electrode; and
a control gate electrode disposed on the block insulating film,
the block insulating film being provided along a bottom surface and a side surface of the control gate electrode.

2. The nonvolatile semiconductor memory device according to claim 1, wherein
a width in a first direction of the block insulating film is larger than a width in the first direction of the floating gate electrode.

3. The nonvolatile semiconductor memory device according to claim 1, wherein
the block insulating film is a stacked body of a plurality of insulating films, and
a first insulating film included in the plurality of insulating films is provided along the bottom surface and the side surface of the control gate electrode.

4. The nonvolatile semiconductor memory device according to claim 3, wherein
another insulating film excluding the first insulating film is disposed at a position between the first insulating film and a surface of the floating gate electrode.

5. The nonvolatile semiconductor memory device according to claim 4, wherein
a width in the first direction of the other insulating film is substantially identical to a width in the first direction of the floating gate electrode.

6. The nonvolatile semiconductor memory device according to claim 3, wherein
another insulating film excluding the first insulating film is disposed at a position between the first insulating film and the bottom surface of the control gate electrode and at a position between the first insulating film and a surface of the floating gate electrode.

7. The nonvolatile semiconductor memory device according to claim 1, further comprising:
an air gap disposed between the floating gate electrode and the control gate electrode that are adjacent to each other,
wherein the floating gate electrode is disposed so as to directly contact the air gap.

8. The nonvolatile semiconductor memory device according to claim 7, wherein
a width in a first direction of the block insulating film is larger than a width in the first direction of the floating gate electrode.

9. The nonvolatile semiconductor memory device according to claim 7, wherein
the block insulating film is a stacked body of a plurality of insulating films, and
a first insulating film included in the plurality of insulating films is provided along the bottom surface and the side surface of the control gate electrode.

10. The nonvolatile semiconductor memory device according to claim 9, wherein
another insulating film excluding the first insulating film is disposed at a position between the first insulating film and a surface of the floating gate electrode.

11. The nonvolatile semiconductor memory device according to claim 10, wherein
a width in the first direction of the other insulating film is substantially identical to a width in the first direction of the floating gate electrode.

12. The nonvolatile semiconductor memory device according to claim 9, wherein
another insulating film excluding the first insulating film is disposed at a position between the first insulating film and the bottom surface of the control gate electrode and at a position between the first insulating film and a surface of the floating gate electrode.

13. A method of manufacturing a nonvolatile semiconductor memory device, comprising:
forming a stacked body of a tunnel insulating film, a floating gate electrode, a first insulating film, and a first sacrifice film on a semiconductor layer;
forming an isolation trench that divides the stacked body in a first direction;
implanting an insulating isolation film in the isolation trench;
removing the first sacrifice film;
forming a second insulating film along a bottom surface and a side surface of a cavity portion at a position where the first sacrifice film was removed; and
depositing a metal film in the cavity portion.

14. The method of manufacturing a nonvolatile semiconductor memory device according to claim 13, comprising:
after removing the first sacrifice film, removing the insulating isolation film to broaden a width in the first direction of the cavity portion.

15. The method of manufacturing a nonvolatile semiconductor memory device according to claim 13, comprising:
after depositing the metal film, removing the insulating isolation film to form an air gap at a position between the floating gate electrode and the metal film.

16. The method of manufacturing a nonvolatile semiconductor memory device according to claim 13, wherein
the second insulating film is a block insulating film disposed between a control gate electrode and the floating gate electrode of a memory cell.
